(19) United States
(12) Patent Application Publication
(10) Pub. No.: US 2008/0318416 A1
(43) Pub. Date: Dec. 25, 2008

(54) METHOD OF IMPROVING INTERCONNECTION BETWEEN ALUMINUM AND COPPER IN SEMICONDUCTOR METAL LINE PROCESS

(76) Inventor: Geon-Hi Kim, Gangnan-gu (KR)

Correspondence Address: SHERR & VAUGHN, PLLC, 620 HERNDON PARKWAY, SUITE 200, HERNDON, VA, 20170, US

(21) Appl. No.: 12/138,015

(22) Filed: Jun. 12, 2008

(30) Foreign Application Priority Data
Jun. 25, 2007 (KR) 10-2007-0062150

(51) Int. Cl. H01L 21/4763

(52) U.S. Cl. 438/643; 257/E21.171

(57) ABSTRACT

A method for enhancing an aluminum-copper interconnection in a semiconductor metal line process. In order to solve a reduction in wafer yield due to copper segregation resulting from a time delay during a metal deposition process, copper precipitates are re-solidified into the aluminum film through a quench process of performing annealing on the wafer at a predetermined temperature for a predetermined time correlating to the time delay.

The present application claims priority under 35 U.S.C. §119 to Korean Patent Application No. 10-2007-0062150 (filed on Jun. 25, 2007), which is hereby incorporated by reference in its entirety.

### BACKGROUND

Typically, aluminum (Al) has been widely used for forming metal lines of semiconductor integrated circuits due to the ease in forming patterns and its physical properties such as having low conductivity, etc. However in recent years, in order to obtain a more highly integrated semiconductor device, a reduced size of the semiconductor circuit is required. Accordingly, a total interconnection of aluminum lines may increase, but a line width decreases. High current densities concentrated on and/or over a metal line to accomplish the previous performance in aluminum lines having such a reduced line width have resulted in the failure of semiconductor devices due to electro-migration (EM), etc.

Accordingly, in order to enhance the EM characteristics in an aluminum line, an AlCu alloy in which a specific amount of copper (Cu) is added to aluminum (Al) has been used. A general circuit structure having an AlCu alloy may include an AlCu metal layer, an upper layer of an anti-reflective coating layer and a lower layer of a barrier film composed of TiN, Ti, TiW and the like to prevent infiltration of impurities into the aluminum and for also increasing adhesion. In devices having this structure, deposition of each layer is performed through one sequence. However, in a metal line process employing an AlCu alloy, there occurs a time delay in which a wafer remains at a specific temperature within a chamber due to the occurrence of several problems after AlCu is deposited during the process. Accordingly, there occurs a problem that copper whose specific amount is added to aluminum to improve EM characteristics when the delay time occurs is segregated. Such segregation of copper serves as blocking at the time of a subsequent metal reactive ion etching (RIE), thereby generating a metal line bridge. The formation of a metal line bridge serves as a main cause in degradation in the yield of semiconductor devices.

### SUMMARY

Embodiments relate to a method of fabricating semiconductor device and, more particularly to, a method of improving an aluminum-copper interconnection to enhance the yield of wafers due to an undesirable copper segregation in a semiconductor metal line process using an AlCu alloy.

Embodiments relate to an AlCu interconnection method in a semiconductor metal line process which enhances the yield of wafers in such a manner that copper precipitates are resolidified into an aluminum film through a quench process during performing an annealing process on a corresponding wafer at a predetermined temperature during a predetermined time according to time delay which occurs within a chamber that has previously caused copper segregation.

Embodiments relate to a method of enhancing the interconnection between aluminum and copper in a semiconductor metal line process that can include at least one of the following steps: depositing a barrier film for metal lines on and/or over an insulating layer on and/or over a wafer; and then depositing an AlCu alloy layer for the metal lines on and/or over an uppermost surface of the barrier film; and then depositing an anti-reflective coating film on and/or over the AlCu alloy layer; and then keeping the wafer in a processing chamber for a predetermined time after depositing the anti-reflective coating film is deposited; and then performing an annealing process on the wafer to prevent segregation of the copper in the AlCu alloy.

Embodiments relate to a method that can include at least one of the following steps: forming a metal layer having an aluminum component and a copper component on a wafer in a chamber; and then forming an anti-reflective coating film on the metal layer; and then maintaining the wafer remains in the chamber for a first predetermined time; and then performing an annealing process on the wafer for a second predetermined time and at a predetermined temperature.

Embodiments relate to a method that can include at least one of the following steps: forming an AlCu alloy layer for metal lines on a wafer in a chamber; and then forming an anti-reflective coating film on the AlCu alloy layer; and then maintaining the wafer remains in the chamber; and then performing an annealing process on the wafer for a predetermined time and a predetermined temperature.

### DRAWINGS

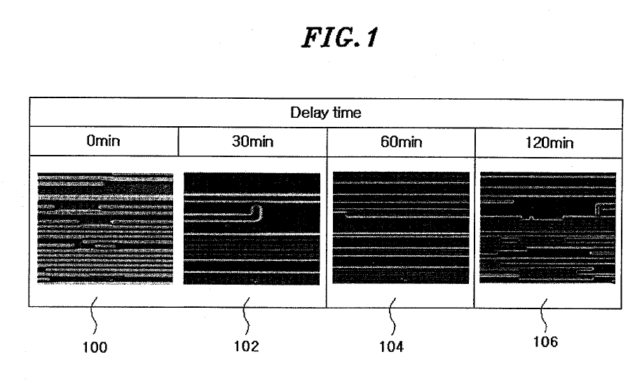

Example FIG. 1 illustrates SEM images of the segregation of copper due to a time delay within a chamber during a semiconductor metal line process.

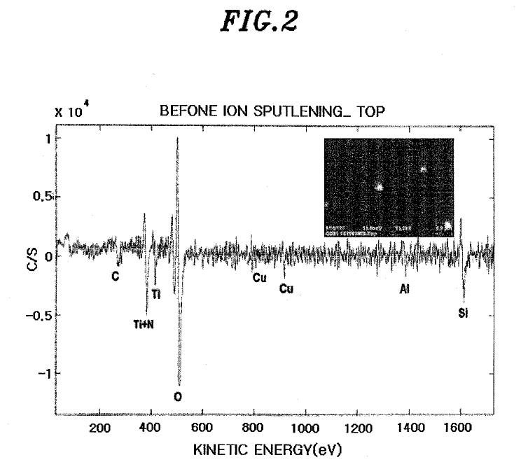

Example FIG. 2 illustrates a graph of an AES analysis into a portion in which copper segregation on a wafer has occurred.

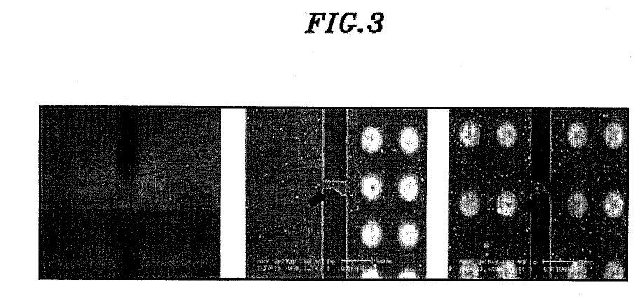

Example FIG. 3 illustrates SEM images for failure mode analysis of a wafer having a 0% yield, in accordance with embodiments.

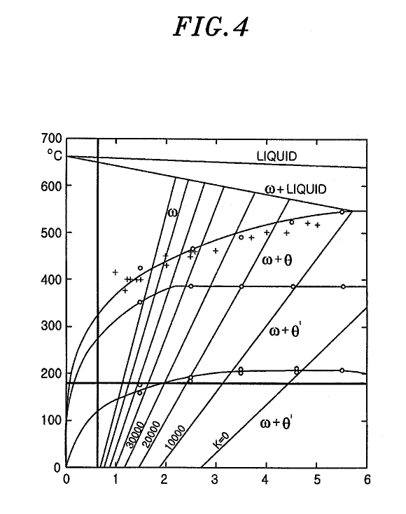

Example FIG. 4 illustrates a graph of a copper heat state diagram according to the weight percentage of copper in aluminum, in accordance with embodiments.

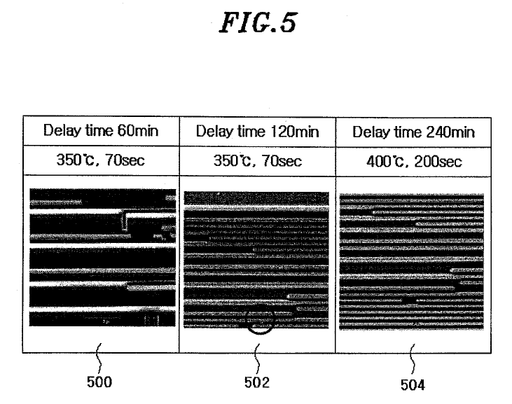

Example FIG. 5 illustrates SEM images of significant reduction in copper segregation using a quench process, in accordance with embodiments.

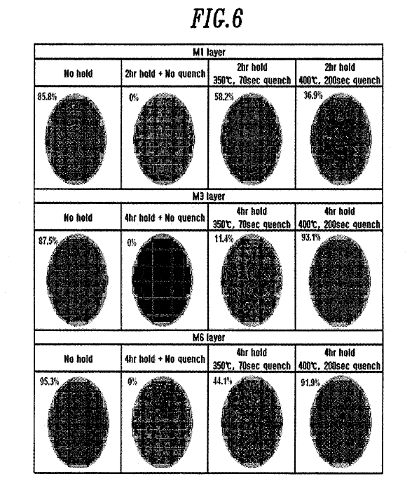

Example FIG. 6 illustrates wafer yield comparison according to whether a quench process was performed, in accordance with embodiments.

### DESCRIPTION

In accordance with embodiments, Table 1 illustrates a comparison of semiconductor substrate which has undergone a metal line process in a processing chamber having a temperature of 200° C., and the degree of copper segregation which occurs between the metal lines due to a time delay during metal line processing time in the chamber and the effects of a rework (quenching) process on the semiconductor substrate before EIR on and/or over the semiconductor substrate.

TABLE 1

| | Time Delay | | |
|---|---|---|---|
| | when depositing | Rework process | Quench |
| No. | a Metal layer | (Quench) | Condition |
| 1 | 0 min | No | — |
| 2 | 30 min | No | — |
| 3 | 60 min | No | — |
| 4 | 120 min | No | — |
| 5 | 60 min | Yes | 350° C./70 sec |
| 6 | 120 min | Yes | 350° C./70 sec |
| 7 | 240 min | Yes | 400° C./200 sec |

Further, experiments for checking the influence on the yield of semiconductor devices when copper segregation occurs, and the amount of re-solidification of copper segregation through the rework process were conducted as illustrated in Table 2. A time delay time was applied to the metal 1, 3, and 6 layer, and copper segregation was viewed using SEM imagery after metal RIE per on and/or a layer basis. When checking the wafer yield, metal line bridges were checked through a failure mode.

TABLE 2

| | M1 Deposition | | M3 Deposition | | M6 Deposition | |
|---|---|---|---|---|---|---|
| No. | Time delay | Quench | Time delay | Quench | Time delay | Quench |
| 1 | — | — | — | — | — | — |
| 2 | 120 min | — | — | — | — | — |
| 3 | 120 min | 350° C./70 sec | — | — | — | — |
| 4 | 120 min | 400° C./200 sec | — | — | — | — |
| 5 | — | — | — | — | — | — |
| 6 | — | — | 240 min | — | — | — |
| 7 | — | — | 240 min | 350° C./70 sec | — | — |
| 8 | — | — | 240 min | 400° C./200 sec | — | — |
| 9 | — | — | — | — | — | — |
| 10 | — | — | — | — | 240 min | — |
| 11 | — | — | — | — | 240 min | 350° C./70 sec |
| 12 | — | — | — | — | 240 min | 400° C./200 sec |

Example FIG. 1 illustrates images of the respective conditions 1, 2, 3, and 4 after experiment simulations were carried out as illustrated in Table 1. As illustrated in example FIG. 1, in sample SEM image (100), when there is no time delay, it can be seen that portions other than metal line patterns formed after metal RIE is performed are subject to etching and oxide portions are clear. However, in sample SEM image (102), when the time delay is 30 min, it can be seen that defects on which etching is not performed on oxide, but remains exist. Moreover, as in sample SEM image (104) and sample SEM image (106), as the time delay increases, the degree of copper segregation becomes severe.

Example FIG. 2 illustrates a graph of AES analysis into a portion in which defects on the semiconductor substrate exist as illustrated in example FIG. 1. As illustrated in the analysis of the graph of example FIG. 2, copper (Cu) components at defect portions were checked. If copper components remain as described above, they become the cause of block etching when subsequent metal RIE is conducted. As illustrated in example FIG. 3, as a result of this phenomenon, a more dense metal line becomes the cause of a metal bridge, and thus, causes a low yield of a resultant semiconductor device based on a failure mode analysis into a wafer whose yield is 0% (zero-yield wafer). Meaning, copper segregation results due to the copper component in the AlCu metal line becoming solidified and segregated due to a time delay. Such copper segregation can also be checked from a heat state diagram according to the copper weight percentage (%). In particular, as can be seen from a copper heat state diagram graph according to the copper weight percentage within aluminum (Al) as illustrated in example FIG. 4, when copper has a 0.5 weight percentage, segregation has occurred because of a phase change of copper when copper is subject to aging in a temperature range of between 120 to 200° C. Accordingly, in the case in which aging occurs in an AlCu alloy due to the occurrence of a time delay within a processing chamber having a certain temperature when Ti (200° C.) or TiN (200° C.) is deposited on the AlCu metal line to form an anti-reflective coating (ARC) film after the AlCu alloy is deposited (300° C.), copper precipitates are generated. Such copper precipitates serve as blocks when subsequent metal RIE is carried out, thereby causing micro bridges.

In accordance with embodiments, in the event of an occurrence of copper segregation due to aging, performing an annealing process at a temperature of 300° C. or more for a predetermined time, copper can be re-solidified into the aluminum film. In accordance with embodiments, in the case in which aging occurs in which a semiconductor substrate remains in a processing chamber having a certain temperature for a certain period of time during metal deposition for a metal interconnection process using a AlCu alloy film, copper may be re-solidified into the aluminum film through an annealing process in a quenching after the metal line process. Accordingly, a significant reduction in copper segregation is achieved. In essence, a subsequent annealing process may be performed on the wafer in a semiconductor metal line process of depositing a barrier film composed of at least one of TiN, Ti and TiW on and/or over the metal lines, on and/or over the insulating layer on and/or over a semiconductor wafer, depositing a AlCu alloy layer for metal lines on and/or over the uppermost surface of the barrier film, and depositing an anti-reflective coating film on and/or over the AlCu alloy layer, in order to prevent copper segregation due to a time delay in which the wafer remains in a chamber after the anti-reflective coating film is deposited.

As illustrated in example FIG. 5, SEM images showing a wafer after metal RIE by after that has undergone a quench process under the conditions illustrated in Table 1, i.e., at 350° C. for 70 sec and 400° C. for 200 sec when time delay were 60 min, 120 min, and 240 min. It can be seen in SEM image (500) of a wafer having a 60 min delay time, copper precipitates were gone when the quench process of 350° C. at 70 sec was carried out, when compared to the SEM images of example FIG. 1. However in SEM image (502) of a wafer having a 120 min delay time, copper segregation was reduced significantly when compared to SEM image (106) when the wafer did not undergo a quench process. Moreover, in SEM image (504), when a quench process of 400° C. for 200 sec was performed on a wafer having a 240 min delay time, copper precipitates were gone. Accordingly, it can be seen that copper components, which were segregated due to a time delay within a processing chamber, were re-solidified into the aluminum film through an appropriate quench process.

Example FIG. 6 illustrates the yield of wafers depending upon if a quench process was performed after a time delay in a 200° C. process chamber in each metal layer, as listed in example Table 2. It can be seen that wafers on which a process was performed without time delay shows a normal yield, and wafers on which a quench process was not performed after a time delay of 120 min or more has a yield of 0% irrespective of a metal layer. This is because, as described above, when a time delay occurs within a chamber of a certain temperature after AlCu is deposited at a certain temperature, copper segregation occurs due to copper aging. Meaning, copper precipitates form micro-bridges of metal lines at the time of metal RIE, degrading the yield. Furthermore, it can be seen that when copper aging occurs due to a time delay of 120 min or more, wafers have a yield which is about 30% lower than that of normal wafers, as illustrated in example FIG. 6. This means that copper precipitates generated due to long-term copper aging are not fully re-solidified into an aluminum film through a quench process, as illustrated in example FIG. 5, but partially remain. It can also be seen that if a quench process of 400° C. for 200 sec is performed although a time delay time of 20 min or more has occurred, the yield was not lowered. As illustrated in example FIG. 5, this means that precipitates caused by copper aging can be fully re-solidified into the aluminum (Al) film through an appropriate quench process.

In accordance with embodiments, in order to solve a reduction in wafer yield due to copper segregation as a result of a time delay within a chamber of a specific temperature during a metal deposition process in a metal interconnection process using an film in which a specific amount of copper is added to aluminum, copper precipitates may be re-solidified into the aluminum film through a quench process. The quench process may be an annealing process on a corresponding wafer at a predetermined temperature for a predetermined time depending upon the time delay causing the copper segregation. Accordingly, the yield of semiconductor devices can be significantly enhanced.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming an insulating layer on a wafer in a chamber; and then
forming a barrier film for metal lines on the insulating layer; and then
forming an AlCu alloy layer for the metal lines on the barrier film; and then
forming an anti-reflective coating film on the AlCu alloy layer; and then
maintaining the wafer remains in the chamber for a predetermined time after forming the anti-reflective coating film; and then
performing an annealing process on the wafer.

2. The method of claim 1, wherein the annealing process is performed on the wafer at a temperature of 350° C. or more for 70 sec or more when the wafer is maintained in the chamber for less than 2 hours after forming the anti-reflective coating film.

3. The method of claim 1, wherein the annealing process is performed on the wafer at a temperature of 400° C. or more for 200 sec or more when the wafer is maintained in the chamber for less than 2 hours after forming the anti-reflective coating film.

4. The method of claim 1, wherein the barrier film comprises any one of TiN, Ti, and TiW.

5. A method comprising:
forming a metal layer having an aluminum component and a copper component on a wafer in a chamber; and then
forming an anti-reflective coating film on the metal layer; and then
maintaining the wafer remains in the chamber for a first predetermined time; and then
performing an annealing process on the wafer for a second predetermined time and at a predetermined temperature.

6. The method of claim 5, wherein the first predetermined time is less than 2 hours and the second predetermined time is 70 seconds or more.

7. The method of claim 6, wherein the predetermined temperature is 350° C.

8. The method of claim 5, wherein the first predetermined time is less than 2 hours and the second predetermined time is 200 seconds or more.

9. The method of claim 8, wherein the predetermined temperature is 400° C. or more.

10. The method of claim 5, wherein the barrier film comprises TiN.

11. The method of claim 5, wherein the barrier film comprises Ti.

12. The method of claim 5, wherein the barrier film comprises TiW.

13. A method comprising:
forming an AlCu alloy layer for metal lines on a wafer in a chamber; and then
forming an anti-reflective coating film on the AlCu alloy layer; and then
maintaining the wafer remains in the chamber; and then
performing an annealing process on the wafer for a predetermined time and a predetermined temperature.

14. The method of claim 13, wherein the predetermined time is 70 sec or more.

15. The method of claim 13, wherein the predetermined temperature is 350° C. or more.

16. The method of claim 13, wherein the predetermined time is 70 sec or more and the predetermined temperature is 350° C.

17. The method of claim 13, wherein the predetermined time is 200 sec or more.

18. The method of claim 13, wherein the predetermined temperature is 400° C. or more.

19. The method of claim 13, wherein the predetermined time is 200 sec or more and the predetermined temperature is 400° C.

20. The method of claim 13, further comprising, before forming the AlCu layer:
forming an insulating layer on the wafer; and then
forming a barrier film on the insulating layer.
